(19) United States
(12) Patent Application Publication
(10) Pub. No.: US 2009/0159896 A1
(43) Pub. Date: Jun. 25, 2009

(54) SILICON CARBIDE MOSFET DEVICES AND METHODS OF MAKING

(75) Inventors: Stephen Daley Arthur, Glenville, NY (US); Kevin Sean Matocha, Rexford, NY (US); Zachary Matthew Stum, Niskayuna, NY (US); Jesse Berkley Tucker, Knightdale, NC (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 11/960,785

(22) Filed: Dec. 20, 2007

(51) Int. Cl. H01L 21/265; H01L 21/336; H01L 29/24

(52) U.S. Cl. 257/77; 438/285; 438/522; 257/E21.409; 257/E21.335; 257/E29.104

(57) ABSTRACT

A method of making a silicon carbide MOSFET is disclosed. The method includes providing a semiconductor device structure, wherein the device structure comprises a silicon carbide semiconductor device layer, an ion implanted well region of a first conductivity type formed in the semiconductor device layer, an ion implanted source region of a second conductivity type formed into the ion implanted well region; providing a mask layer over the semiconductor device layer, the mask layer exposing a portion of the ion implanted source region, then etching through the portion of the ion implanted source region to form a dimple; then implanting ions through the dimple to form a high dopant concentration first conductivity type ion implanted contact region, wherein the ion implanted contact region is deeper than the ion implanted well region; then removing the contact region mask layer and annealing implanted ions.

### BACKGROUND

The invention relates generally to semiconductor devices and fabrication methods.

Silicon carbide (SiC) is a wide band gap semiconductor with intrinsic properties that are suited for high power, high temperature, and high frequency operation. In addition, SiC is the only known wide band gap semiconductor that has silicon dioxide (SiO₂) as its native oxide. This property makes SiC desirable for the fabrication of metal oxide semiconductor field effect transistors (MOSFETs).

Silicon carbide (SiC) metal oxide semiconductor field effect transistors (MOSFETs) are also believed to possess material properties that are potentially beneficial for high power switching applications. SiC semiconductor devices can operate at temperatures in excess of 200° C. Because SiC is a crystalline substance that can endure very high temperatures, the need for device cooling is reduced. SiC also has high breakdown field, which is about ten times that of silicon, and a higher thermal conductivity, which is about three times that of silicon.

Short channel lengths are necessary for favorable SiC MOSFET performance as inversion mobility in SiC is limited, and other factors (e.g. channel length) may also be optimized to compensate for the limited inversion mobility. Further, it would be desirable to have a device structure that would make the device robust against high avalanche energy. A robust device structure would allow for energy associated with avalanche to be dissipated across a large area.

Therefore there is a need for a more robust silicon carbide MOSFET device with better performance.

### BRIEF DESCRIPTION

One embodiment disclosed herein is a method of making a silicon carbide MOSFET. The method includes providing a semiconductor device structure, wherein the device structure comprises a silicon carbide semiconductor device layer, an ion implanted well region of a first conductivity type formed in the semiconductor device layer, an ion implanted source region of a second conductivity type formed into the ion implanted well region; providing a mask layer over the semiconductor device layer, the mask layer exposing a portion of the ion implanted source region; then etching through the portion of the ion implanted source region to form a dimple; then implanting ions through the dimple to form a high dopant concentration first conductivity type ion implanted contact region, wherein the ion implanted contact region is deeper than the ion implanted well region; then removing the contact region mask layer; and annealing the implanted ions.

Another embodiment disclosed herein is a method of making a silicon carbide MOSFET. The method includes providing a semiconductor device structure, wherein the device structure comprises an n-type silicon carbide device layer, a p-type well region formed in the silicon carbide layer, an n-type ion implanted source region formed into the ion implanted well region; forming a dimple in the source region; implanting ions through the dimple to form a p+ contact region, wherein the p+ contact region is deeper than p-type well region; then removing the contact region mask layer; and annealing implanted ions in the well, source, and contact regions at temperatures greater than 1500 degree C.

Another embodiment disclosed herein is a silicon carbide vertical MOSFET. The vertical MOSFET includes a gate dielectric region, a silicon carbide drift region, a well region of a first conductivity type situated in the drift region, a source region of a second conductivity type situated in the well region, and a dimpled contact region of the first conductivity type, wherein the dimpled contact region is wholly below the level of the source region.

### DRAWINGS

These and other features, aspects, and advantages of the present invention will become better understood when the following detailed description is read with reference to the accompanying drawings in which like characters represent like parts throughout the drawings, wherein:

FIGS. 1-13 schematically represent the cross-sectional side views of the fabrication stages of a silicon carbide MOSFET in accordance with one embodiment of the present invention.

### DETAILED DESCRIPTION

Embodiments of the present invention include methods of fabricating silicon carbide MOSFET devices. In the following specification and the claims that follow, the singular forms “a”, “an” and “the” include plural referents unless the context clearly dictates otherwise. As used herein, the terms “disposed over” or “deposited over” refer to disposed or deposited immediately on top of and in contact with, or disposed or deposited on top of but with intervening layers therebetween.

A method of making a silicon carbide (SiC) MOSFET includes forming a dimpled contact region that is deeper than a well region in the MOSFET. Although the applicants do not wish to be bound by any particular theory, it is believed that the deeper contact region will be the place where avalanche sets in under high reverse bias as the SiC device layer is thinner underneath the dimpled contact region. When driving the device into avalanche, the avalanche current is expected to flow into all the contact regions distributed across the active area of the device (not just a single spot). This allows the energy associated with avalanche to be dissipated across a large area and makes the device “robust.”

Embodiments of the method include forming a semiconductor device structure including a silicon carbide semiconductor device layer, an ion implanted well region of a first conductivity type formed in the semiconductor device layer, and an ion implanted source region of a second conductivity type formed into the ion implanted well region. The method further includes forming a high dopant concentration dimpled contact region of the first conductivity type deeper than the well region. In one embodiment, the source region is etched prior to implantation of the contact region. This enables the use of a continuous resist mask with patterned holes only where the first conductivity type-high dopant concentration contact region is intended. The dimpled contact region not only enables the formation of a low resistance ohmic contact to the well region but also provides greater surface area to make contact to the well region.

In presently known techniques for silicon devices, the dopants for the contact region are diffused into the device layer prior to the source implant and resist plugs are used to mask the source region implant. When cell dimensions get very small, the small resist plugs tend to have poor adhesion and get knocked out of place prior to the source region implant. Embodiments of the present invention avoid this drawback.

Embodiments of the invention further include method steps for the formation of controllable short channels to be formed in inversion mode SiC MOSFETs using removable spacer structures.

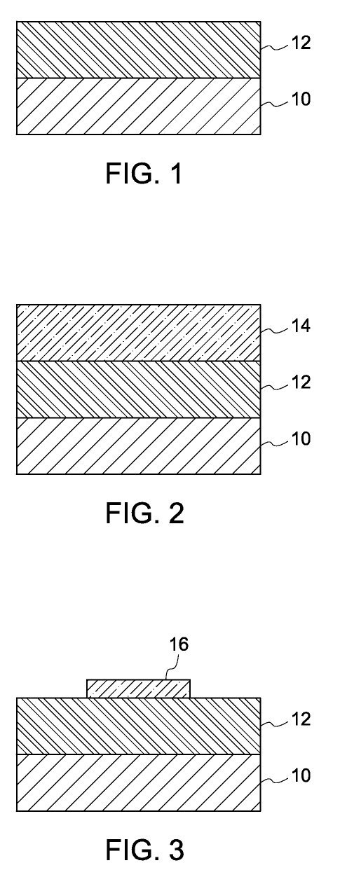

FIGS. 1-13 schematically represent a process for fabricating a silicon carbide MOSFET in accordance with one embodiment of the present invention. In one embodiment, the MOSFET is a vertical MOSFET. The method step illustrated in FIG. 1 includes providing a substrate 10 and disposing a silicon carbide semiconductor device layer 12 over the substrate. In the illustrated embodiment, the device layer 12 is a drift layer in a vertical MOSFET. The device layer 12 may be epitaxially grown over the substrate 10. For example, a deposition technique such as, chemical vapor deposition (CVD) may be performed to form the device layer 12. The substrate and the SiC device layer may be n-type or p-type. The SiC device layer 10 may be a polytype of silicon carbide, such as 4H SiC, or 6H SiC polytypes. In certain embodiments, the thickness of the semiconductor layer 10 may be in a range of 1 micron to 150 microns.

In a non-limiting example, the substrate is a heavily doped n+ SiC substrate and the SiC semiconductor device layer is also of n-type. The dopant concentration in the substrate may be in a range from 10¹⁸ cm⁻³ to 10²¹ cm⁻³. The dopant concentration in the SiC semiconductor device layer may be in a range from 10¹⁴ cm⁻³ to 10¹⁷ cm⁻³.

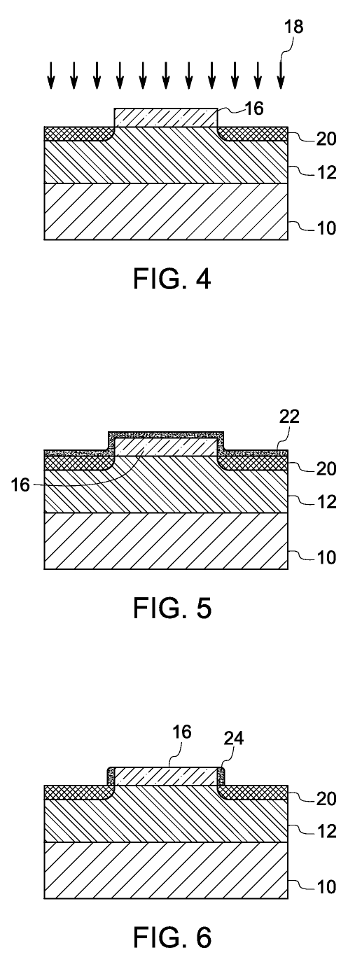

The method step as illustrated in FIG. 2 includes growing or depositing a first conformal layer 14 of sufficient thickness over the device layer 12 to block subsequent implants and in the method step illustrated in FIG. 3, the first conformal layer 14 is etched to form the implant mask layer 16. The well region implant mask layer comprises one or more sidewalls In a non-limiting example, a straight dry etch process is used to create one or more geometrically defined edges of the one or more respective sidewalls. Ion implantation 18 is performed to form one or more well regions 20 as illustrated in FIG. 4. The energy at which the ions are implanted to form the well region may be in a range from 10 keV to 2 MeV. In one example, the well region is a p-well region. In certain embodiments a dopant concentration in the well region is in a range from 1×10 to 1×10 cm⁻³. In some embodiments, a well region depth is in a range from 0.4 microns to 2 microns.

FIGS. 5 and 6 illustrate the steps of forming a source region implant mask spacer. FIG. 5 illustrates the deposition of a second conformal layer over the ion implant mask layer, and results of the anisotropic directional etching of the second conformal layer are illustrated in FIG. 6. In one example, the anisotropic directional etching includes reactive ion etching. Directional dry etch processing of the second conformal layer is such that the final spacer width is highly correlated to the deposited thickness (and thus channel length control is provided). In one embodiment, the width of the implant mask spacer is selected to be in a range from 0.2 microns to 2 microns.

The method may further include the step of monitoring and controlling a thickness of the second conformal layer during formation of the second conformal layer. The thickness can be accurately monitored with standard film thickness metrology tools for mean thickness and thickness variation.

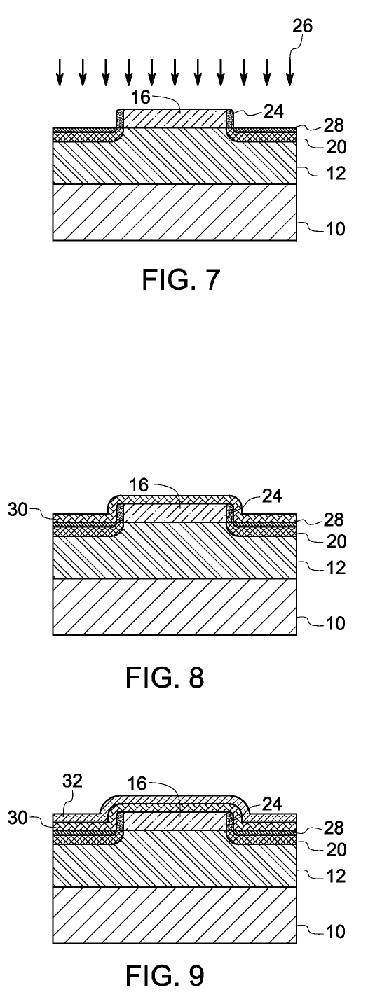

In the step illustrated in FIG. 7, ion implantation is performed to form the source region 28. In one example, if the well region is p-doped, the source region is an n-doped region. In some embodiments, the energy at which the ions are implanted to form the well region is in a range from 10 keV to 2 MeV. In certain embodiments, the source region has a dopant concentration in a range from 1×10¹⁶ to 1×10¹⁸ cm⁻³.

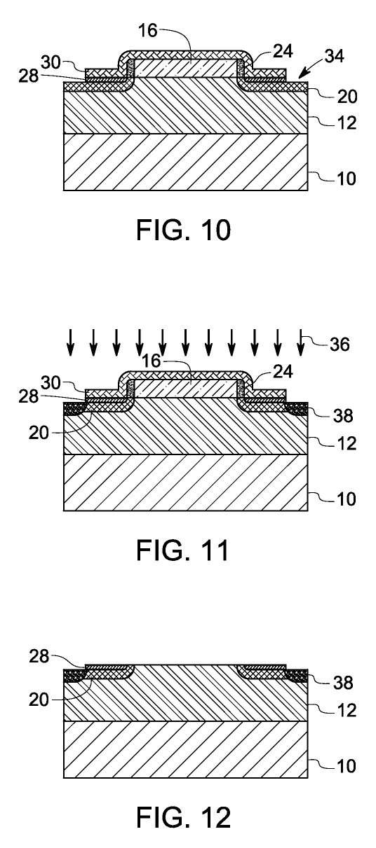

FIG. 8 illustrates disposing or depositing a conformal high temperature oxide (HTO) layer 30 over source and well regions, the well region implant mask layer and the source region implant mask spacers. In FIG. 9, a photoresist layer 32 is disposed over the conformal high temperature oxide (HTO) layer. The photoresist layer is then etched to form the contact region mask layer and expose a portion of the source region. This is followed by etching of the source region 28 to form the dimple 34 as illustrated in FIG. 10.

In one alternate embodiment, the well region implant mask layer and the source region implant mask spacers are removed prior to disposing or depositing a conformal high temperature oxide (HTO) layer 30 described in FIG. 8. In another alternate embodiment, after disposing the layer 30, the layer 30 is anisotropically etched to form contact region mask spacers, similar to the source region implant mask spacers. This may be followed by vertical etching of the source region 28, for example, by inductively coupled plasma etching to form the dimple 34.

FIG. 11 illustrates the process of ion implantation to form a high dopant concentration contact region 38. In one embodiment, the contact region has a dopant concentration in a range from 1×10¹⁸ to 1×10²¹ cm⁻³. The contact region 38 is deeper than the well region 20. In some embodiments, the energy at which the ions are implanted to form the contact region is in a range from 5 keV to 300 keV. In some embodiments, the contact region depth is in a range from 0.5 microns to 10 microns. In certain embodiments, the contact region depth is in a range from 1 micron to 5 microns.

Following implantation, the well region mask layer, the well region implant mask layer, the source region implant mask spacer and the contact region mask layer or spacers are removed to result in the structure illustrated in FIG. 12. The implanted ions are then subjected to annealing. In one example, the annealing is carried out at temperatures greater than 1500° C. In a further example, the annealing is carried out at temperatures in the range from 1400° C. to 1800° C. In one embodiment, exposure to high temperature helps, for example, in the electrical activation of ion-implanted species.

The well region mask layer, the source region implant mask spacers, and the contact region mask layer discussed herein may include materials with sufficient ion stopping power required to mask the implanted ions and which can be selectively removed from the SiC surface without surface damage. Suitable examples include silicon nitride, silicon oxide, photoresist, amorphous carbon, sapphire, and aluminum nitride.

As will be appreciated, a MOSFET having a p-doped layer or region with p-type dopants may be doped with dopants such as but not limited to boron, aluminum, gallium, magnesium, carbon, calcium, or any combinations thereof. A MOSFET having an n-doped layer or region with n-type dopants may be doped with dopants such as but not limited to nitrogen, phosphorus, arsenic, antimony, or any combinations thereof. In context of epitaxial growth, for example using a deposition technique such as chemical vapor deposition (CVD), the dopants may be introduced during the growth process. Alternatively, the dopants may be introduced by ion implantation or diffusion processes.

In one embodiment, prior to ion implantation, a screening layer may be at least partially disposed over the semiconductor device layer to protect the device layer surface. Suitable materials for the screening layer include but are not limited to carbon, silicon dioxide, silicon nitride, photoresist, sapphire, and aluminum nitride. The formation of the screening layer may be through thermal oxidation in some embodiments while, in certain other embodiments, deposition techniques such as CVD may be employed to form the screening layer. The screening layer may be disposed uniformly over a patterned masking layer and the exposed portion at a desirable thickness. In some embodiments, the thickness of the screening layer may be in a range from 50 Å to 1000 Å.

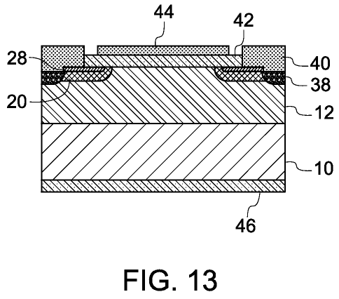

The method may further include the step of forming a gate dielectric layer 42 (shown in FIG. 13) over the semiconductor device layer, subsequent to the annealing of the implanted ions and the removal of all masking layers and masking spacers. The formation, in one example, is through thermal oxidation of the SiC followed by annealing at a high temperature. In another example, a low temperature chemical vapor deposition (CVD) technique may be used to form a thin oxide layer. The gate dielectric may include materials such as but not limited to silicon oxide and silicon nitride.

The method may further include the steps of forming source contacts 40 and gate electrode 44. The illustrated MOSFET device shown in FIG. 13 further includes a drain contact 46.

Another embodiment is a silicon carbide vertical MOSFET. The vertical MOSFET includes a gate dielectric region, a silicon carbide drift region, a well region of a first conductivity type situated in the drift region, a source region of a second conductivity type situated in the well region, and a dimpled contact region of the first conductivity type. The dimpled contact region is situated wholly below the level of the source region. In one embodiment, the vertical MOSFET device exhibits greater robustness against high avalanche energy.

In some embodiments, the channel region, the source region, and a portion of the drift region are situated on a common plane as illustrated in FIG. 13. In certain embodiments, the source region is wholly embedded in the well region. As used herein, the term “wholly embedded in the well region” refers to the source region being formed wholly in the well region and having a top surface at or below the common plane as shown in FIG. 13.

Many currently known vertical MOSFETs exhibit Ids (source to drain current) versus V_{ds} (source to drain voltage) characteristics and saturate at lower current densities (less than 500 Amps/cm²), even at full gate drive (high gate source voltage, for example 18 volts). In accordance with one embodiment of the present invention, the I_{ds} of the vertical MOSFET does not saturate even at high current densities of 500 Amps/cm² at full gate drive (gate source voltage of 18 volts).

In some embodiments, the vertical MOSFET device has channel lengths below 2 microns. In some further embodiments, the vertical MOSFET device has channel lengths 1 micron. In some still further embodiments, the vertical MOSFET device has channel lengths below 0.5 microns.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method of making a silicon carbide MOSFET comprising:
providing a semiconductor device structure, wherein the device structure comprises a silicon carbide semiconductor device layer, an ion implanted well region of a first conductivity type formed in the semiconductor device layer, an ion implanted source region of a second conductivity type formed into the ion implanted well region;
providing a mask layer over the semiconductor device layer, the mask layer exposing a portion of the ion implanted source region; then
etching through the portion of the ion implanted source region to form a dimple; then
implanting ions through the dimple to form a high dopant concentration first conductivity type ion implanted contact region, wherein the ion implanted contact region is deeper than the ion implanted well region; then
removing the contact region mask layer; and
annealing implanted ions.

2. The method of claim 1, wherein providing the semiconductor device structure comprises forming the ion implanted well region by:
providing a well region implant mask layer over the semiconductor device layer, the well region implant mask layer comprising one or more sidewalls; and
implanting ions in an unmasked region of the semiconductor device layer to form the ion implanted well region of a first conductivity type.

3. The method of claim 2, wherein providing the well region implant mask layer comprises:
forming a first conformal layer over the device layer; and
using a straight dry wall etch process to create one or more geometrically defined edges of the one or more respective sidewalls.

4. The method of claim 2, wherein providing the semiconductor device structure comprises forming the ion implanted source region by:
providing one or more source region implant mask spacers adjacent to the one or more sidewalls of the well region implant mask layer; and
implanting ions in a portion of the ion implanted well region to form an aligned ion implanted source region of a second conductivity type.

5. The method of claim 4, wherein forming one or more source region implant mask spacers comprises:
forming a second conformal layer over the ion implant mask layer and the device layer; and
anisotropic directional etching the second conformal layer.

6. The method of claim 5, wherein the anisotropic directional etching comprises reactive ion etching.

7. The method of claim 5, wherein a width of the one or more source region implant mask spacers is correlated to the thickness of the second conformal layer.

8. The method of claim 5, further comprising monitoring and controlling a thickness of the second conformal layer during formation of the second conformal layer.

9. The method of claim 5, wherein providing the contact region mask layer comprises:
providing a conformal high temperature oxide (HTO) layer over the well region implant mask layer, the one or more source region implant mask spacers, and the ion implanted well and source regions;
providing a resist layer over the HTO layer;
etching an unmasked region of the HTO layer to form the contact region mask layer, wherein the contact region mask layer exposes a portion of the ion implanted source region.

10. The method of claim 9, further comprising removing the well region mask layer and source region implant mask layer subsequent to forming the ion implanted contact region and prior to annealing implanted ions, wherein annealing implanted ions comprises annealing the implanted ions in the well, source, and contact regions.

11. The method of claim 1, wherein the annealing comprises annealing at temperatures greater that 1500 degree C.

12. The method of claim 1, wherein the well region has a dopant concentration in a range from 1×10¹⁶ to 1×10¹⁸ cm⁻³.

13. The method of claim 1, wherein the source region has a dopant concentration in a range from 1×10¹⁸ to 1×10²¹ cm⁻³.

14. The method of claim 1, wherein the contact region has a dopant concentration in a range from 1×10¹⁸ to 1×10²¹ cm⁻³.

15. The method of claim 1, wherein the semiconductor device layer is of first conductivity type.

16. The method of claim wherein the first conductivity type is n-type.

17. The method of claim 1, further comprising forming ohmic contacts in contact with the contact region.

18. The method of claim 1, further comprising forming a gate dielectric layer over the semiconductor device layer, subsequent to the annealing of the implanted ions.

19. A method of making a silicon carbide MOSFET comprising:
providing a semiconductor device structure, wherein the device structure comprises an n-type silicon carbide device layer, a p-type well region formed in the silicon carbide layer, an n-type ion implanted source region formed into the ion implanted well region;
forming a dimple in the source region;
implanting ions through the dimple to form a p+ contact region, wherein the p+ contact region is deeper than p-type well region; then removing the contact region mask layer; and
annealing implanted ions in the well, source, and contact regions at temperatures greater than 1500 degree C.

20. A vertical silicon carbide MOSFET comprising:
a gate dielectric region;
a silicon carbide drift region;
a well region of a first conductivity type situated in the drift region;
a source region of a second conductivity type situated in the well region; and
a dimpled contact region of the first conductivity type, wherein the dimpled contact region is situated wholly below the level of the source region.

21. The vertical MOSFET of claim 20, wherein a channel region, the source region, and a portion of the drift region are situated on a common plane.

22. The vertical MOSFET of claim 21, wherein the source region is wholly embedded in the well region.

23. The vertical MOSFET of claim 20, wherein a channel length is less than 1 micron.

24. The vertical MOSFET of claim 20, wherein a depth of the well region is in a range from 0.4 microns to 2 microns.

25. The vertical MOSFET of claim 20, wherein a depth of the contact region is in a range from 0.5 microns to 5 microns.

26. The vertical MOSFET of claim 20, wherein a drain-source current I_{ds} at full gate drive does not saturate at current densities of 500 Amps/cm².
